(19) United States
(12) Patent Application Publication
(10) Pub. No.: US 2008/0192413 A1
(43) Pub. Date: Aug. 14, 2008

(54) Weatherproofed Assembly For Housing Electronic Hardware

(75) Inventors: Jon Reid, New South Wales (AU); Michael Soire, New South Wales (AU)

Correspondence Address: BOWDITCH & DEWEY, LLP, 311 MAIN STREET, P.O. BOX 15156, WORCESTER, MA, 01615-0156, US

(73) Assignee: Bio Recongnition Systems Pty Ltd, Lane Cove (AU)

(21) Appl. No.: 11/909,583

(22) PCT Filed: Mar. 24, 2006
(86) PCT No.: PCT/AU2006/000399

§ 371 Date: Sep. 24, 2007

(30) Foreign Application Priority Data
Mar. 24, 2005 (AU) 2005901471

(51) Int. Cl. H05K 5/06

(52) U.S. Cl. 361/679

(57) ABSTRACT

Weatherproofed assembly for housing electronic hardware, the assembly comprising a back plate arranged for fastening to a surface and a front housing arranged for, at least partially, containing the electronic hardware. The front housing including a sealing member, wherein the front housing is further arranged for fastening to the back plate so that during the fastening, the sealing member sealingly engages the back plate to weatherproof the electronic hardware within the assembly.

### OVERVIEW

The invention relates to a weather proof housing for electronic hardware. In particular, the device is a new way of attaching hardware componentry to any surface at any angle, where a weather proofed and secure seal is required.

The device incorporates a metal backplate, a front housing and a silicon sealing gasket. The device uses a simple compression method to seal but allows for external user control, to be provided without breaking the weather proof seal. The device is therefore designed for wet, dry, arid, salt and harsh environments where strong weather resistance is required but without making use of the product difficult.

The design shown in the photographs and drawings is a security and time & attendance device, but the principal can be utilized in the design of any product requiring the above specifications.

### SUMMARY OF INVENTION

According to a first aspect, the invention consists in a weatherproofed assembly for housing electronic hardware, the assembly comprising
a back plate arranged for fastening to a surface and
a front housing arranged for, at least partially, containing the electronic hardware, the front housing including a sealing member,
wherein the front housing is further arranged for fastening to the back plate so that, during the fastening, the sealing member sealingly engages the back plate to weatherproof the electronic hardware within the assembly.

Preferably, the back plate and the front housing are arranged so that, for fastening of the front housing to the back plate, the front housing is rotated with respect to the back plate, the rotation resulting in the front housing being compressed against, and fastened to, the back plate.

Preferably, the back plate and the front housing are arranged so that, to fasten the front housing to the back plate, the housing is presented to the back plate in an off rotational alignment, so that rotation of the front housing with respect to the back plate to effect the fastening brings the front housing into a rotationally alignment with the back plate.

Preferably, the back plate comprises at least one longitudinal keyhole and the front housing comprises at least one key member having a head formation arranged for engaging with a respective one of the at least one key holes to effect the fastening of the front housing to the back plate.

Preferably, the at least one keyhole includes an opening, arranged to receive the respective head formation, and an engagement section configured to, upon rotation of the front housing, retain the head formation and effect the fastening.

Preferably, the engagement section of at least one keyhole includes at least one tapered edge arranged to abuttingly engage with the head formation of a respective key member, thus causing the rotation of the front housing with respect to the back plate to result in the front housing being compressed against the back plate.

Preferably, at least one of the key members is a screw or a bolt arranged to screw into a respective boss formation of the front housing.

Preferably, the at least one boss formation includes a limiter for restricting the insertion length of the respective screw or bolt so that, when in contact with the limiter, the head of the screw or bolt is in a position to engage with the respective keyhole, when the front housing is presented to the back plate.

Preferably, the sealing member is arranged to protectively house the electronics hardware within the front housing.

Preferably, the sealing member comprises a peripheral engagement edge, defining a first opening, the engagement edge being arranged to, when the front housing is fastened to the back plate, be depressed to the back plate so as to close the first opening and effect the weatherproofed sealing of the electronic hardware.

Preferably, the peripheral edge includes a sealing lip arranged to sealingly engage with the back plate.

Preferably, the front housing comprises an interaction opening and the sealing member further comprises a second opening, the second opening including a peripheral sealing flange and being arranged so that, upon fastening of the front housing to the back plate, the second opening aligns and sealingly engages with the interaction opening of the front housing to define a sealed interaction window for allowing an electrical contact between an element of the electronic hardware and an external object.

Preferably, the electronic hardware is related to fingerprint scanning device and includes a fingerprint sensor, the interaction window allowing a finger to be depressed against an fingerprint sensor so as to effect a fingerprint scan.

Preferably, at least one of the front housing and the back plate is made of plastic cast aluminium, magnesium and aluminium or plastic, and the sealing member is made of silicon, rubber or soft plastic material.

### DRAWINGS

A preferred embodiment of the invention is illustrated in the attached drawings, in which

FIG. 1 is a cross sectioned side elevation of the front housing and back plate.

FIG. 2 is a side elevation of a seal

FIG. 3 is a side elevation of the back plate

FIG. 4 is a plan view of the back plate

FIG. 5 is a perspective view of the back plate

FIG. 6 is an underside view of the front housing

FIG. 7 is a sectional view of the rim of the seal

FIG. 8 is an underside view of the back plate.

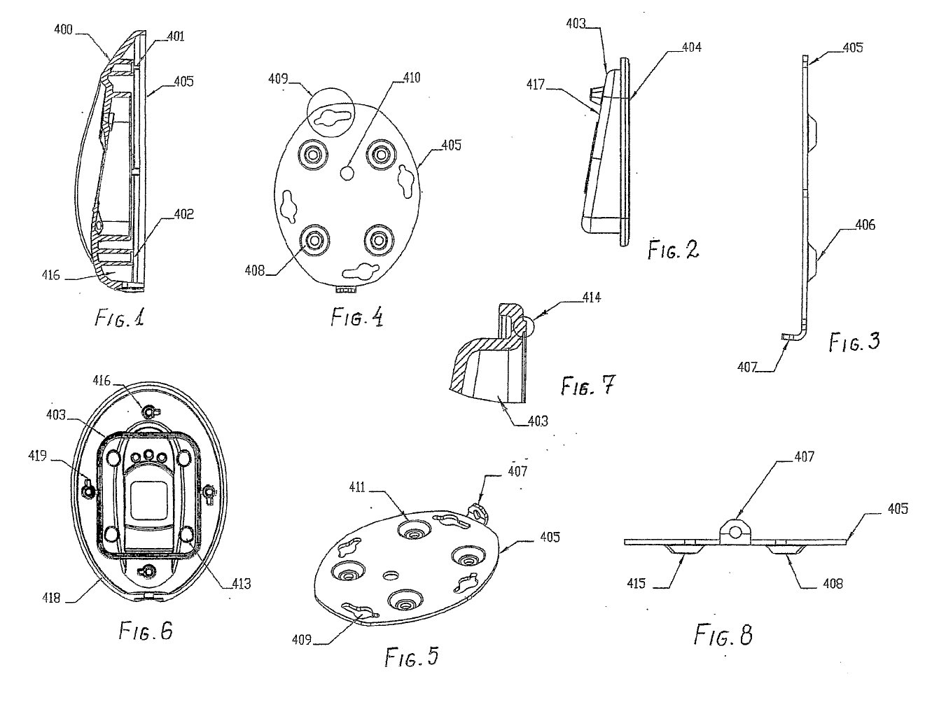

### DESCRIPTION

Typically, the device is attached to a vertical surface, such as an exterior wall, by means of engagement of the heads of four screws with four receptor keyways provided in a backing plate mounted on the said surface. Initially the device is offered up to the backing plate slightly rotated from its final position to allow engagement of said heads in said keyway whereupon on rotation of the housing in relation to the back plate the housing is locked to the base plate. A further, final screw can then be inserted to immovably lock the housing onto the back plate.

An elliptical metal backing plate 405 is made of any reasonably heavy gauge steel, coated for weather protection. It has four tapered rebate holes having upper and lower edges 411 mounted symmetrically or non symmetrically on its surface for securing to a substrate, typically the surface of an exterior wall. At the bottom of each rebate is a hole 408 to allow the backing plate to be semi-permanently secured onto a substrate of any description (not shown), the rims of the holes also forming their own weather proofing seal once attached to the substrate. Each of the rebated holes are countersunk to hide the heads of the screws (not shown) used to secure the backing plate onto the substrate. The countersunk holes also provide further clearance and an anti tampering seal to the front housing once mated with the bracket. All holes and rebates except the keys are located within the confines of the outer edge or rim seal 414 of the silicon gasket. Four laser cut or punched out keyholes 409 are also provided in the backing plate on the circumference of an imaginary circle to allow rotational movement of the housing in relation to the backing plate. The bracket also contains a positioning hole 407 which is used to position, lock and fasten the front housing to the bracket once mated together. Wiring and other associated electronics exit the backing plate via a hole 410 fitted with a rubber grommet (not shown) for weather proofing.

In the preferred embodiment, the electronics is disposed within silicon gasket/seal 403, which is inserted into the front housing 400. When the front housing is engaged with the backing plate gasket/seal 403 is depressed and seals the electronics within the housing to weatherproof it. The gasket/seal 403 is designed with one or more front apertures 417 for any sensor, switch or control interface required to be made available to a user through the front of the housing shell. This is achieved by cutting the appropriate hole or creating a bubble around the device being used for the control. The seal periphery of the hole is arranged in a form of a flange. When the housing is attached to the backing plate, the flange is depressed to provide sealing for the user interaction aperture. This design allows for the use of human interaction sensors or devices requiring human touch, feel, press or control to be made available from the confines of the device but without compromising weather resistivity. The silicon gasket seal rim 404 at the back of the seal/gasket has a specially designed lip 414 that makes contact with the backing plate and also creates a compression seal when the front housing and metal plate are brought together. The small cross-sectional area of the lip allows good seal to be created with very little pressure.

Of course, an embodiment wherein the seal does not include the electronics, but is in a simple form of a sealing rim engaged around the periphery of the housing openings. When the housing is attached to the backing plate, the rim is depressed to effect a compression around the openings to weatherproof the electronics within the housing.

The front housing is provided with four protruding metal bosses 416 into which self tapper screws (not shown) may be inserted (401, 402). Limiters 419 can be used to limit the insertion length of the respective screw or bolt so that, when in contact with the limiter 419, the head of the screw or bolt is in a position to engage with the respective keyhole, when the front housing is presented to the back plate. The front housing is attached to the metal bracket 405 by locating the heads of the self tapper screws into the centres of each of the four keyways 409. When all four keyways have their respective screw heads inserted, the lip of the front housing will be flush with the back plate. At this point the front housing can be manually turned clockwise approximately 5 degrees to the position where it will no longer rotate because the screw shanks have reached the limit of the keyways. At this point the locking screw hole 407 at the bottom of the metal bracket will align with the slot in the bottom of the housing 400 and a screw inserted from the exterior of the housing shell causes the housing to be immovably engaged with the backing plate.

The terms “comprising” and “including” (and their grammatical variations), as used herein, are used in the inclusive sense of “having” and not in the exclusive sense of “consisting only of”.

The claims defining the invention are as follows:

1. Weatherproofed assembly for housing electronic hardware, the assembly comprising
a back plate arranged for fastening to a surface and
a front housing arranged for, at least partially, containing the electronic hardware, the front housing including a sealing member,
wherein the front housing is further arranged for fastening to the back plate so that, during the fastening, the sealing member sealingly engages the back plate to weatherproof the electronic hardware within the assembly.

2. The assembly of claim 1, wherein the back plate and the front housing are arranged so that, for fastening of the front housing to the back plate, the front housing is rotated with respect to the back plate, the rotation resulting in the front housing being compressed against, and fastened to, the back plate.

3. The assembly of claim 2, wherein the back plate and the front housing are arranged so that, to fasten the front housing to the back plate, the housing is presented to the back plate in an off rotational alignment, so that rotation of the front housing with respect to the back plate to effect the fastening brings the front housing into a rotationally alignment with the back plate.

4. The assembly of claim 2, wherein the back plate comprises at least one longitudinal keyhole and the front housing comprises at least one key member having a head formation arranged for engaging with a respective one of the at least one key holes to effect the fastening of the front housing to the back plate.

5. The assembly of claim 4, wherein the at least one keyhole includes an opening, arranged to receive the respective head formation, and an engagement section configured to, upon rotation of the front housing, retain the head formation and effect the fastening.

6. The assembly of claim 5, wherein the engagement section of at least one keyhole includes at least one tapered edge arranged to abuttingly engage with the head formation of a respective key member, thus causing the rotation of the front housing with respect to the back plate to result in the front housing being compressed against the back plate.

7. The assembly of claim 4, wherein at least one of the key members is a screw or a bolt arranged to screw into a respective boss formation of the front housing.

8. The assembly of claim 7, wherein the at least one boss formation includes a limiter for restricting the insertion length of the respective screw or bolt so that, when in contact with the limiter, the head of the screw or bolt is in a position to engage with the respective keyhole, when the front housing is presented to the back plate.

9. The assembly of claim 1, wherein the sealing member is arranged to protectively house the electronics hardware within the front housing.

10. The assembly of claim 1, wherein the sealing member comprises a peripheral engagement edge, defining a first opening, the engagement edge being arranged to, when the front housing is fastened to the back plate, be depressed to the back plate so as to close the first opening and effect the weatherproofed sealing of the electronic hardware.

11. The assembly of claim 10, wherein the peripheral edge includes a sealing lip arranged to sealingly engage with the back plate.

12. The assembly of claim 10, wherein the front housing comprises an interaction opening and the sealing member further comprises a second opening, the second opening including a peripheral sealing flange and being arranged so that, upon fastening of the front housing to the back plate, the second opening aligns and sealingly engages with the interaction opening of the front housing to define a sealed interaction window for allowing an electrical contact between an element of the electronic hardware and an external object.

13. The assembly of claim 12, wherein the electronic hardware is related to fingerprint scanning device and includes a fingerprint sensor, the interaction window allowing a finger to be depressed against an fingerprint sensor so as to effect a fingerprint scan.

14. The assembly of claim 1 wherein at least one of the front housing and the back plate is made of plastic cast aluminium, magnesium and aluminium or plastic, and the sealing member is made of silicon, rubber or soft plastic material.
